(19) United States
(12) Patent Application Publication
(10) Pub. No.: US 2025/0239467 A1
(43) Pub. Date: Jul. 24, 2025

(54) APPARATUS AND METHOD FOR DICING A WAFER

(71) Applicant: Samsung Electronics Co., Ltd., Suwon-si (KR)

(72) Inventor: Hyun Soo KIM, Suwon-si (KR)

(21) Appl. No.: 18/799,182

(22) Filed: Aug. 9, 2024

(30) Foreign Application Priority Data
Jan. 18, 2024 (KR) 10-2024-0008018

(51) Int. Cl. H01L 21/67; H01L 21/78

(52) U.S. Cl. CPC H01L 21/67092; H01L 21/78

(57) ABSTRACT

An apparatus for dicing a wafer includes a stage on which the wafer is positioned, a light source providing a light beam, a beam splitter splitting the light beam into first and second split light beams, a first objective lens focusing the first split light beam on the wafer and cutting the wafer along a first dicing line using the first split light beam, and a second objective lens spaced apart from the first objective lens, focusing the second split light beam on the wafer and cutting the wafer along a second dicing line using the second split light beam, wherein the apparatus adjusts a position at which the second split light beam is focused on the wafer such that a spacing between the first and second dicing lines is adjusted, and the wafer is cut simultaneously along the first and second dicing lines.

### CROSS-REFERENCE TO RELATED APPLICATION

This application claims priority under 35 U.S.C. § 119 to Korean Patent Application No. 10-2024-0008018, filed on Jan. 18, 2024, in the Korean Intellectual Property Office, and all the benefits accruing therefrom under 35 U.S.C. § 119, the contents of which in its entirety are herein incorporated by reference.

### BACKGROUND

### Technical Field

The present disclosure relates to an apparatus for dicing a wafer and a method for dicing a wafer.

### Description of Related Art

In order to divide a wafer into semiconductor chips, a dicing process is required to perform cutting of the wafer. Conventionally, a dicing process in which a wafer is cut using a single light beam irradiated from a single light source is performed. In this case, a time for which the dicing process is performed may increase, reducing the efficiency of the dicing process. For this reason, research is underway to increase the efficiency of the dicing process.

### SUMMARY

A purpose of the present disclosure is to provide an apparatus for dicing a wafer and a method for dicing a wafer in which a single light beam is split into two split light beams, and a wafer is cut simultaneously along two dicing lines using the two split light beams, thereby improving the efficiency of the dicing process.

Moreover, another purpose of the present disclosure is to provide an apparatus for dicing a wafer and a method for dicing a wafer in which a dicing process is performed on a plurality of wafers with different spacings between dicing lines in a single apparatus for dicing a wafer, thereby improving the efficiency of the dicing process.

Moreover, still another purpose of the present disclosure is to provide an apparatus for dicing a wafer and a method for dicing a wafer in which a portion of the wafer is cut by performing a second dicing process using a second light beam having a smaller wavelength and a lower power than those of a first light beam, and then a remaining portion of the wafer is cut by additionally performing a first dicing process using the first light beam, thereby preventing a portion of the wafer from being unseparated during the dicing process, thereby improving the efficiency of the dicing process.

According to some embodiments of the present disclosure, there is provided an apparatus for dicing a wafer, comprising a stage on which the wafer is positioned, a light source for providing a first light beam, a beam splitter splitting the first light beam into a first split light beam and a second split light beam, a first objective lens focusing the first split light beam on the wafer, the first objective lens cutting the wafer along a first dicing line extending in a first horizontal direction using the first split light beam, and a second objective lens spaced apart from the first objective lens in a second horizontal direction different from the first horizontal direction, the second objective lens focusing the second split light beam on the wafer, the second objective lens cutting the wafer along a second dicing line extending in the first horizontal direction using the second split light beam, wherein the second dicing line is spaced apart from the first dicing line in the second horizontal direction, wherein the apparatus adjusts a position at which the second split light beam is focused on the wafer in the second horizontal direction such that a spacing in the second horizontal direction between the first dicing line and the second dicing line is adjusted, and wherein the wafer is cut simultaneously along the first dicing line and the second dicing line.

According to some embodiments of the present disclosure, there is provided an apparatus for dicing a wafer, comprising a stage on which the wafer is positioned, a light source for providing a first light beam, a beam splitter splitting the first light beam into a first split light beam and a second split light beam, a first objective lens focusing the first split light beam on the wafer, the first objective lens cutting the wafer along a first dicing line extending in a first horizontal direction using the first split light beam, a second objective lens spaced apart from the first objective lens in a second horizontal direction different from the first horizontal direction, the second objective lens focusing the second split light beam on the wafer, the second objective lens cutting the wafer along a second dicing line extending in the first horizontal direction using the second split light beam, and a reflective mirror reflecting the second split light beam split from the beam splitter and providing the second split light beam to the second objective lens, wherein the second dicing line is spaced apart from the first dicing line in the second horizontal direction, and wherein the apparatus adjusts an angle of the reflective mirror to adjust a spacing in the second horizontal direction between the first dicing line and the second dicing line.

According to some embodiments of the present disclosure, there is provided a method for dicing a wafer, comprising loading the wafer onto a stage, wherein the wafer includes a substrate including silicon (Si), a first layer including a material different from a material of the substrate and disposed on an upper surface of the substrate, and a second layer including a material different from the material of the first layer and disposed on an upper surface of the first layer, providing a first light beam generated from a light source to a beam splitter, splitting the first light beam into a first split light beam and a second split light beam using the beam splitter, providing the first split light beam to a first objective lens, and providing the second split light beam to a second objective lens, focusing the first split light beam on a first dicing line extending in a first horizontal direction on the wafer using the first objective lens, and focusing the second split light beam on a second dicing line extending in the first horizontal direction on the wafer using the second objective lens, and cutting the wafer along the first dicing line using the first split light beam, and cutting the wafer along the second dicing line using the second split light beam, wherein the second objective lens is spaced apart from the first objective lens in a second horizontal direction different from the first horizontal direction, wherein the second dicing line is spaced apart from the first dicing line in the second horizontal direction, wherein the method adjusts a position at which the second split light beam is focused on the wafer in the second horizontal direction to adjust a spacing in the second horizontal direction between the first dicing line and the second dicing line, and wherein the wafer is cut simultaneously along the first dicing line and the second dicing line.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

Specific details of other embodiments are included in the detailed description and drawings.

### BRIEF DESCRIPTION OF DRAWINGS

The above and other aspects and features of the present disclosure will become more apparent by describing in detail some embodiments thereof with reference to the attached drawings, in which:

FIG. 1 is a diagram for illustrating an apparatus for dicing a wafer according to example embodiments of the present disclosure;

FIG. 2 is a diagram for illustrating a plurality of dicing lines of an apparatus for dicing a wafer according to example embodiments of the present disclosure;

FIG. 3 and FIG. 4 are diagrams for illustrating an operation of an apparatus for dicing a wafer according to example embodiments of the present disclosure;

FIG. 5 and FIG. 6 are diagrams for illustrating a method for dicing a wafer according to example embodiments of the present disclosure;

FIGS. 7 to 10 are diagrams for illustrating a method for dicing a wafer according to further example embodiments of the present disclosure;

FIG. 11 is a diagram for illustrating an apparatus for dicing a wafer according to further example embodiments of the present disclosure;

FIG. 12 is a diagram for illustrating an apparatus for dicing a wafer according to further example embodiments of the present disclosure;

FIG. 13 and FIG. 14 are diagrams for illustrating an operation of an apparatus for dicing a wafer according to further example embodiments of the present disclosure; and

FIG. 15 is a diagram for illustrating an apparatus for dicing a wafer according to further example embodiments of the present disclosure.

### DETAILED DESCRIPTIONS

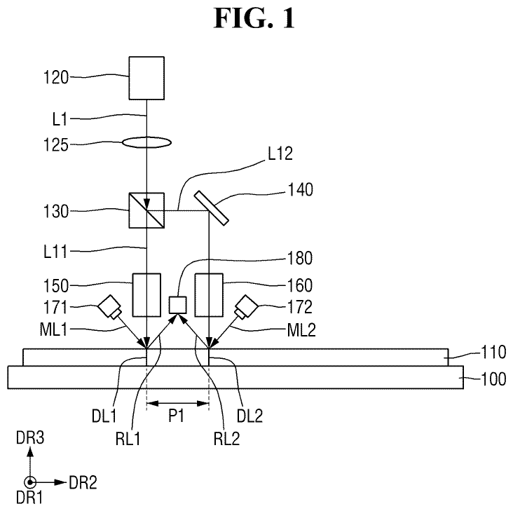

Like reference characters refer to like elements throughout. Hereinafter, an apparatus for dicing a wafer according to example embodiments of the present disclosure is described with reference to FIGS. 1 to 4.

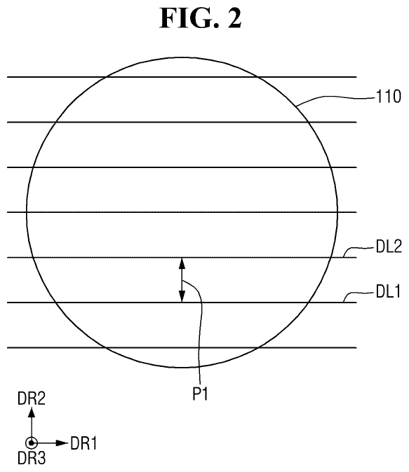

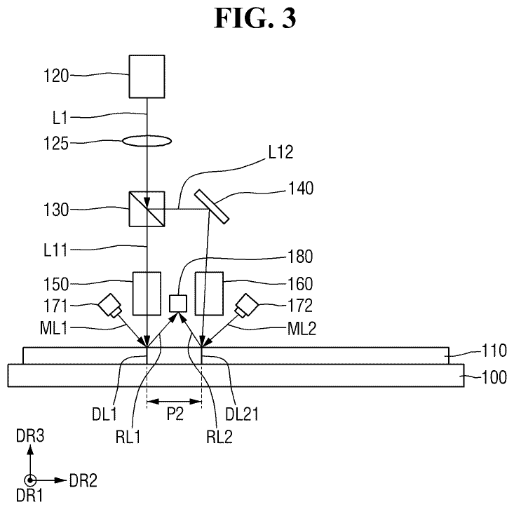

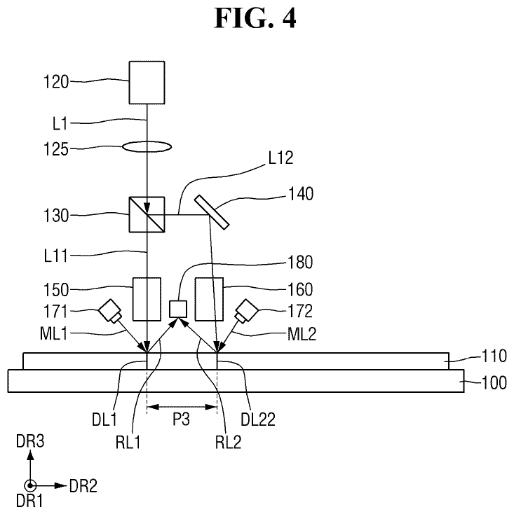

FIG. 1 is a diagram for illustrating an apparatus for dicing a wafer according to example embodiments of the present disclosure. FIG. 2 is a diagram illustrating a plurality of dicing lines of an apparatus for dicing a wafer according to example embodiments of the present disclosure. FIG. 3 and FIG. 4 are diagrams for illustrating an operation of an apparatus for dicing a wafer according to example embodiments of the present disclosure.

Referring to FIGS. 1 to 4, an apparatus for dicing a wafer according to some embodiments of the present disclosure includes a stage 100, a light source 120, a lens 125, a beam splitter 130, a reflective mirror 140, a first objective lens 150, a second objective lens 160, a first sensor 171, a second sensor 172, and a detector 180.

The stage 100 may be a part on which the wafer 110 is positioned while a dicing process is performed. That is, the wafer 110 may be positioned on an upper surface of the stage 100. Hereinafter, each of a first horizontal direction DR1 and a second horizontal direction DR2 may be defined as a direction parallel to the upper surface of the stage 100. The second horizontal direction DR2 may be defined as a direction orthogonal to the first horizontal direction DR1. A vertical direction DR3 may be defined as a direction perpendicular to the upper surface of the stage 100. That is, the vertical direction DR3 may be defined as a direction perpendicular to each of the first horizontal direction DR1 and the second horizontal direction DR2.

A plurality of dicing lines may be formed on the wafer 110. Each of the plurality of dicing lines may extend in the first horizontal direction DR1. The plurality of dicing lines may be spaced apart from each other in the second horizontal direction DR2. While the dicing process is performed, each of the plurality of dicing lines may be a line along which the wafer 110 is cut. For example, each of a first dicing line DL1 and a second dicing line DL2 may extend in the first horizontal direction DR1 and may be formed on the wafer 110. The second dicing line DL2 may be spaced apart from the first dicing line DL1 in the second horizontal direction DR2. While the dicing process is performed, the wafer 110 may be cut along each of the first dicing line DL1 and the second dicing line DL2.

The light source 120 may provide a first light beam L1. For example, the first light beam L1 provided from the light source 120 may travel through the lens 125 and be provided to the beam splitter 130. FIG. 1 shows that one lens 125 is disposed between the light source 120 and the beam splitter 130. However, this is for convenience of illustration, and the present disclosure is not limited thereto. In further some embodiments, at least one of a component that adjusts a wavelength of the first light beam L1, an additional lens, and a reflective mirror may be disposed between the light source 120 and the beam splitter 130.

The beam splitter 130 may receive the first light beam L1 provided from the light source 120. The beam splitter 130 may split the first light beam L1 provided from the light source 120 into a first split light beam L11 and a second split light beam L12. For example, the first split light beam L11 from the beam splitter 130 may be provided to the first objective lens 150. Moreover, the second split light beam L12 from the beam splitter 130 may be provided to the second objective lens 160.

For example, a reflective mirror 140 may be disposed in a path along which the second split light beam L12 from the beam splitter 130 is provided to the second objective lens 160. The second split light beam L12 from the beam splitter 130 may be reflected from the reflective mirror 140 and then may be provided to the second objective lens 160. For example, an angle of the reflective mirror 140 may be adjusted. Thus, an incident angle at which the second split light beam L12 reflected from the reflective mirror 140 is incident to the second objective lens 160 may be adjusted. A detailed description thereof will be provided later.

The first objective lens 150 may receive the first split light beam L11 from the beam splitter 130. The first objective lens 150 may focus the first split light beam L11 on the wafer 110. For example, the first objective lens 150 may focus the first split light beam L11 on the first dicing line DL1 formed on the wafer 110. The first objective lens 150 may cut the wafer 110 in the first horizontal direction DR1 along the first dicing line DL1 using the first split light beam L11.

The second objective lens 160 may receive the second split light beam L12 from the beam splitter 130. The second objective lens 160 may focus the second split light beam L12 on the wafer 110. For example, the second objective lens 160 may focus the second split light beam L12 on the second dicing line DL2 formed on the wafer 110. The second dicing line DL2 may be spaced apart from the first dicing line DL1 in the second horizontal direction DR2. The second objective lens 160 may cut the wafer 110 in the first horizontal direction DR1 along the second dicing line DL2 using the second split light beam L12.

For example, cutting the wafer 110 in the first horizontal direction DR1 along the first dicing line DL1 using the first split light beam L11 may be performed simultaneously with cutting the wafer 110 in the first horizontal direction DR1 along the second dicing line DL2 using the second split light beam L12. That is, the wafer 110 may be cut simultaneously along the first dicing line DL1 and the second dicing line DL2.

The first sensor 171 may be disposed at a side of the first objective lens 150. For example, the first sensor 171 may be disposed on a sidewall of the first objective lens 150. For example, the first sensor 171 may be disposed on the sidewall in the second horizontal direction DR2 of the first objective lens 150. FIG. 1 shows that the first sensor 171 is spaced apart from the sidewall of the first objective lens 150 in the second horizontal direction DR2. However, the present disclosure is not limited thereto. In other example embodiments, the first sensor 171 may contact the sidewall of the first objective lens 150. The first sensor 171 may irradiate first measuring light ML1 on the wafer 110 along the first dicing line DL1.

The second sensor 172 may be disposed at a side of the second objective lens 160. For example, the second sensor 172 may be disposed on a sidewall of the second objective lens 160. For example, the second sensor 172 may be disposed on the sidewall in the second horizontal direction DR2 of the second objective lens 160. FIG. 1 shows that the second sensor 172 is spaced apart from the sidewall of the second objective lens 160 in the second horizontal direction DR2. However, the present disclosure is not limited thereto. In other example embodiments, the second sensor 172 may contact the sidewall of the second objective lens 160. The second sensor 172 may radiate the second measuring light ML2 onto the wafer 110 along the second dicing line DL2.

The detector 180 may be disposed at a side of each of the first objective lens 150 and the second objective lens 160. For example, the detector 180 may be disposed on a sidewall of each of the first objective lens 150 and the second objective lens 160. For example, the detector 180 may be disposed between the first objective lens 150 and the second objective lens 160. The detector 180 may receive first reflected light RL1 generated when the first measuring light ML1 is reflected from the wafer 110 along the first dicing line DL1. Moreover, the detector 180 may receive second reflected light RL2 generated when the second measuring light ML2 is reflected from the wafer 110 along the second dicing line DL2.

The detector 180 may measure a thickness in the vertical direction DR3 of the wafer 110 along the first dicing line DL1 using the received first reflected light RL1. Moreover, the detector 180 may measure a thickness in the vertical direction DR3 of the wafer 110 along the second dicing line DL2 using the received second reflected light RL2. For example, the detector 180 may measure simultaneously the thickness in the vertical direction DR3 of the wafer 110 along the first dicing line DL1 and the thickness in the vertical direction DR3 of the wafer 110 along the second dicing line DL2.

For example, after measuring the thickness in the vertical direction DR3 of the wafer 110 along the first dicing line DL1, the wafer 110 may be cut along the first dicing line DL1. Moreover, after measuring the thickness in the vertical direction DR3 of the wafer 110 along the second dicing line DL2, the wafer 110 may be cut along the second dicing line DL2. However, the present disclosure is not limited thereto. In further some embodiments, cutting the wafer 110 along the first dicing line DL1 and measuring the thickness in the vertical direction DR3 of the wafer 110 along the first dicing line DL1 may be performed simultaneously. Cutting the wafer 110 along the second dicing line DL2 and measuring the thickness in the vertical direction DR3 of the wafer 110 along the second dicing line DL2 may be simultaneously performed.

A position of the wafer 110 at which the second split light beam L12 is focused on the wafer 110 may be adjusted along the second horizontal direction DR2, so that a spacing P1 in the second horizontal direction DR2 between the first dicing line DL1 and the second dicing line DL2 may be adjusted. For example, referring to FIG. 3, the angle of the reflective mirror 140 may be adjusted. An angle at which the second split light beam L12 reflected from the reflective mirror 140 whose angle has been changed is incident on the second objective lens 160 may be changed. A position on which the second split light beam L12 reflected from the reflective mirror 140 whose angle has been changed is focused may be defined as a first changed dicing line DL21. For example, a spacing P2 in the second horizontal direction DR2 between the first dicing line DL1 and the first changed dicing line DL21 in FIG. 3 may be smaller than the spacing P1 in the second horizontal direction DR2 between the first dicing line DL1 and the second dicing line DL2 in FIG. 1.

For example, referring to FIG. 4, the angle of the reflective mirror 140 may be adjusted. An angle at which the second split light beam L12 reflected from the reflective mirror 140 whose angle has been changed is incident on the second objective lens 160 may be changed. A position on which the second split light beam L12 reflected from the reflective mirror 140 whose angle has been changed is focused may be defined as a second changed dicing line DL22. For example, a spacing P3 in the second horizontal direction DR2 between the first dicing line DL1 and the second changed dicing line DL22 in FIG. 4 may be larger than the spacing P1 in the second horizontal direction DR2 between the first dicing line DL1 and the second dicing line DL2 in FIG. 1.

That is, as shown in FIG. 3 and FIG. 4, the angle of the reflective mirror 140 may be adjusted such that the angle at which the second split light beam L12 is incident on the second objective lens 160 may be adjusted, and a position of the second dicing line (e.g., second dicing line DL2 in FIG. 1) may be changed to the first changed dicing line DL21 of FIG. 3 or the second changed dicing line DL22 of FIG. 4. Thus, the spacing in the second horizontal direction DR2 between the first dicing line DL1 and the second dicing line DL2 in FIG. 1 may be adjusted.

The apparatus for dicing a wafer 110 according to example embodiments of the present disclosure may split a single light beam L1 provided from the light source 120 into the two split light beams L11 and L12, and may cut simultaneously the wafer 110 along the two dicing lines DL1 and DL2 using the two split light beams L11 and L12. Thus, the apparatus for dicing a wafer 110 according to some embodiments of the present disclosure may reduce a time duration for which the dicing process is performed to improve the efficiency of the dicing process.

Moreover, the apparatus for dicing the wafer 110 according to example embodiments of the present disclosure may adjust the spacing between the two dicing lines DL1 and DL2 by adjusting the angle of the reflective mirror 140. That is, the apparatus for dicing the wafer 110 according to some embodiments of the present disclosure may adjust the angle of the reflective mirror 140 in the single apparatus for dicing the wafer 110 and thus perform the dicing process on wafers 110 with different spacings between the dicing lines. Thus, the apparatus for dicing the wafer 110 according to some embodiments of the present disclosure may improve the efficiency of the dicing process.

Hereinafter, a method for dicing a wafer according to example embodiments of the present disclosure is described with reference to FIGS. 1 to 6.

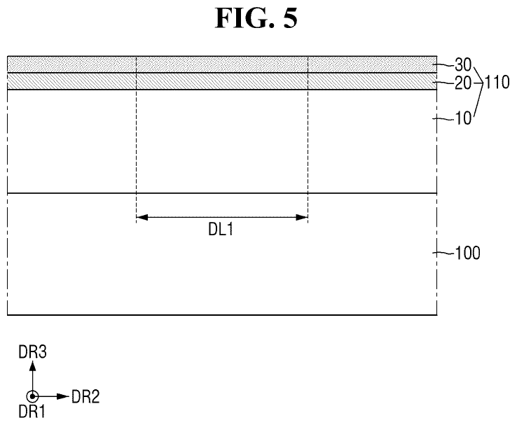

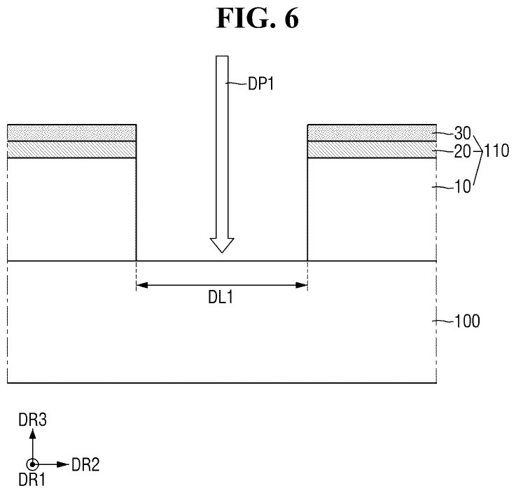

FIG. 5 and FIG. 6 are diagrams for illustrating a method for dicing a wafer according to example embodiments of the present disclosure.

Referring to FIG. 1 and FIG. 5, the wafer 110 may be loaded on the upper surface of the stage 100. For example, the wafer 110 may include a substrate 10, a first layer 20, and a second layer 30. For example, the substrate 10 may include silicon (Si). The substrate 10 may be positioned on the upper surface of the stage 100 so as to contact the upper surface of the stage 100. The first layer 20 may be formed on an upper surface of the substrate 10. For example, the first layer 20 may include a different material than that of the substrate 10. The first layer 20 may include a plurality of patterns. The second layer 30 may be formed on an upper surface of the first layer 20. For example, the second layer 30 may include a different material than that of the first layer 20. The second layer 30 may include a plurality of patterns. That is, the substrate 10 of the wafer 110 may be positioned to contact the upper surface of the stage 100, and an upper surface of the second layer 30 may be exposed.

Subsequently, the first sensor 171 irradiates the first measuring light ML1 on the wafer 110 along the first dicing line DL1. The second sensor 172 may radiate the second measuring light ML2 onto the wafer 110 along the second dicing line DL2. The detector 180 may receive the first reflected light RL1 generated when the first measuring light ML1 is reflected from the wafer 110 along the first dicing line DL1. Moreover, the detector 180 may receive the second reflected light RL2 generated when the second measuring light ML2 is reflected from the wafer 110 along the second dicing line DL2. The detector 180 may measure the thickness in the vertical direction DR3 of the wafer 110 along the first dicing line DL1 using the received first reflected light RL1. Moreover, the detector 180 may measure the thickness in the vertical direction DR3 of the wafer 110 along the second dicing line DL2 using the received second reflected light RL2.

Referring to FIG. 1 and FIG. 6, a first dicing process DP1 on the wafer 110 may be performed. For example, the first dicing process DP1 may sequentially cut the second layer 30, the first layer 20, and the substrate 10. For example, the first light beam L1 generated from the light source 120 may travel through the lens 125 and be provided to the beam splitter 130. The beam splitter 130 may split the first light beam L1 provided from the light source 120 into the first split light beam L11 and the second split light beam L12. The first split light beam L11 may be provided to the first objective lens 150. Moreover, the second split light beam L12 may be provided to the second objective lens 160.

Each of the first split light beam L11 and the second split light beam L12 may be focused on the upper surface of the second layer 30. For example, the first objective lens 150 may focus the first split light beam L11 on the first dicing line DL1 formed on the wafer 110. Moreover, the second objective lens 160 may focus the second split light beam L12 on the second dicing line DL2 formed on the wafer 110.

Each of the first split light beam L11 and the second split light beam L12 may sequentially cut the second layer 30, the first layer 20, and the substrate 10. For example, the first objective lens 150 may cut the wafer 110 in the first horizontal direction DR1 along the first dicing line DL1 using the first split light beam L11. The second objective lens 160 may cut the wafer 110 in the first horizontal direction DR1 along the second dicing line DL2 using the second split light beam L12. For example, the wafer 110 may be cut simultaneously along the first dicing line DL1 and the second dicing line DL2.

The method for dicing the wafer according to some embodiments of the present disclosure may split a single light beam L1 provided from the light source 120 into the two split light beams L11 and L12, and may cut simultaneously the wafer 110 along the two dicing lines DL1 and DL2 using the two split light beams L11 and L12. Thus, the method for dicing the wafer according to some embodiments of the present disclosure may improve the efficiency of the dicing process by reducing the time duration for which the dicing process is performed.

For example, after the cutting process of the wafer 110 is completed in the first dicing process DP1, the wafer 110 may be unloaded from the upper surface of the stage 100. Subsequently, another wafer 110 may be loaded onto the upper surface of the stage 100. For example, a spacing in the second horizontal direction DR2 between two dicing lines formed on another wafer 110 may be different from the spacing P1 in the second horizontal direction DR2 between the first dicing line DL1 and the second dicing line DL2 formed on the wafer 110.

For example, referring to FIG. 3, when two dicing lines formed on another wafer 110 correspond to the first dicing line DL1 and the first changed dicing line DL21, respectively, the angle of the reflective mirror 140 may be adjusted as shown in FIG. 3 and then a dicing process on the wafer 110 may be performed. For example, referring to FIG. 4, when two dicing lines formed on another wafer 110 correspond to the first dicing line DL1 and the second changed dicing line DL22, respectively, the angle of the reflective mirror 140 may be adjusted as shown in FIG. 4 and then a dicing process on the wafer 110 may be performed. In other words, the method for dicing the wafer 110 according to example embodiments of the present disclosure may adjust a position at which the second split light beam is focused on the wafer 110 in the second horizontal direction DR2 such that the spacing between the first dicing line DL1 and the second dicing line DL2 may be adjusted.

Thus, the method for dicing the wafer 110 according to some embodiments of the present disclosure may adjust the angle of the reflective mirror 140 in a single apparatus for dicing a wafer 110 such that the dicing process may be performed on wafers 110 having different spacings between the dicing lines. Thus, the method for dicing the wafer 110 according to some embodiments of the present disclosure may improve the efficiency of the dicing process.

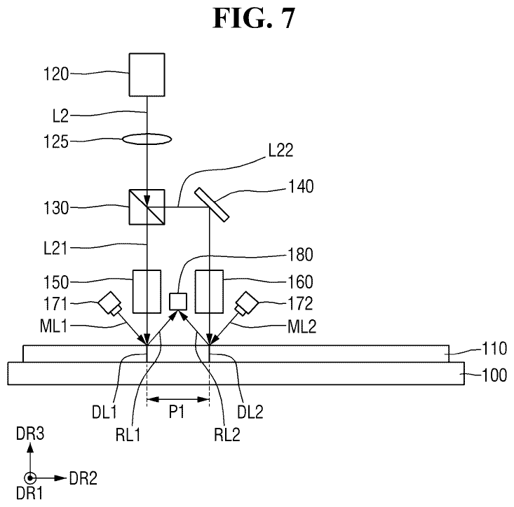

Hereinafter, a method for dicing a wafer according to further example embodiments of the present disclosure is described with reference to FIGS. 7 to 10. The following description focuses on differences thereof from the method for dicing the wafer as shown in FIG. 1 to FIG. 6. Duplicative descriptions are not repeated.

FIGS. 7 to 10 are diagrams for illustrating a method for dicing a wafer according to further example embodiments of the present disclosure.

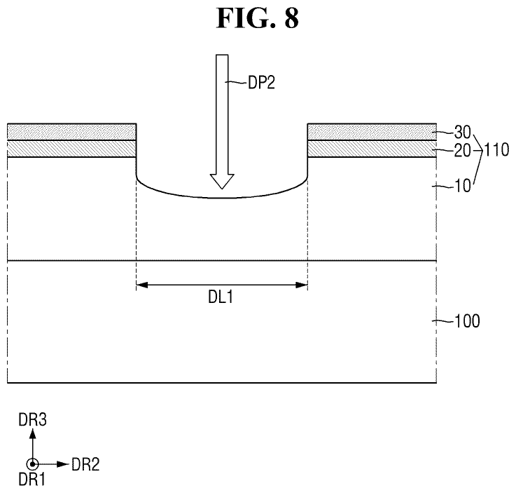

Referring to FIG. 7 and FIG. 8, the wafer 110 may be loaded on the upper surface of the stage 100. For example, the wafer 110 may include the substrate 10, the first layer 20 formed on the upper surface of the substrate 10, and the second layer 30 formed on the upper surface of the first layer 20. The substrate 10 may be positioned on the upper surface of the stage 100 so as to contact the upper surface of the stage 100. The upper surface of the second layer 30 may be exposed. Subsequently, using the first sensor 171, the second sensor 172, and the detector 180, the thickness in the vertical direction DR3 of the wafer 110 along the first dicing line DL1 and the thickness in the vertical direction DR3 of the wafer 110 along the second dicing line DL2 may be measured.

Subsequently, a second dicing process DP2 on the wafer 110 may be performed. For example, the second dicing process DP2 may sequentially cut the second layer 30, the first layer 20, and a portion of the substrate 10. After the second dicing process DP2 has been completed, a remaining portion of the substrate 10 may remain uncut.

For example, a second light beam L2 generated from the light source 120 may travel through the lens 125 and be provided to the beam splitter 130. For example, the second light beam L2 may have a smaller wavelength than that of the first light beam L1 in FIG. 1 and FIG. 6. Moreover, the second light beam L2 may have power smaller than that of the first light beam L1 in FIG. 1 and FIG. 6. The beam splitter 130 may split the second light beam L2 provided from the light source 120 into a third split light beam L21 and a fourth split light beam L22. The third split light beam L21 may be provided to the first objective lens 150. Moreover, the fourth split light beam L22 may be provided to the second objective lens 160.

Each of the third split light beam L21 and the fourth split light beam L22 may be focused on the upper surface of the second layer 30. For example, the first objective lens 150 may focus the third split light beam L21 on the first dicing line DL1 formed on the wafer 110. Moreover, the second objective lens 160 may focus the fourth split light beam L22 on the second dicing line DL2 formed on the wafer 110.

Each of the third split light beam L21 and the fourth split light beam L22 may sequentially cut the second layer 30, the first layer 20, and the portion of the substrate 10. For example, the first objective lens 150 may cut a portion of the wafer 110 in the first horizontal direction DR1 along the first dicing line DL1 using the third split light beam L21. The second objective lens 160 may cut a portion of the wafer 110 in the first horizontal direction DR1 along the second dicing line DL2 using the fourth split light beam L22. For example, a portion of the wafer 110 may be cut simultaneously along the first dicing line DL1 and the second dicing line DL2.

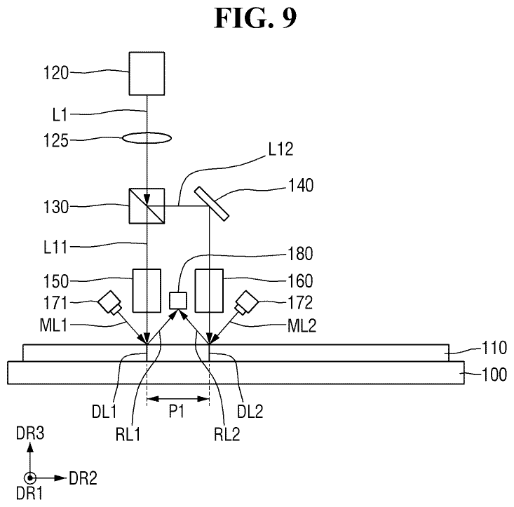

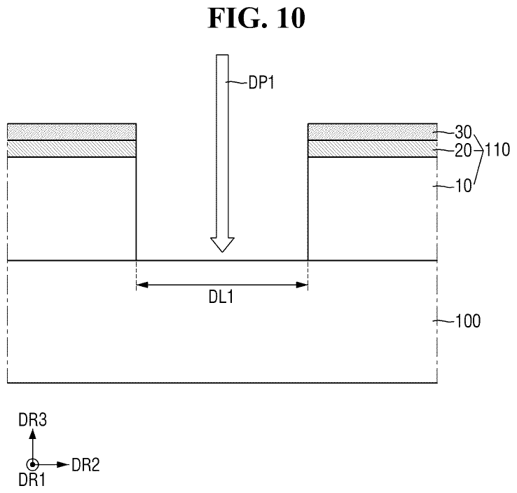

Referring to FIG. 9 and FIG. 10, the first dicing process DP1 on the wafer 110 may be performed. For example, the first dicing process DP1 may cut a remaining portion of the substrate 10 that remains after the second dicing process DP2 in FIG. 8 has been completed. The first dicing process DP1 as shown in FIG. 9 and FIG. 10 may be the same as the first dicing process DP1 as described above with reference to FIG. 5 and FIG. 6. Therefore, detailed description of the first dicing process DP1 as shown in FIG. 9 and FIG. 10 is omitted.

The method for dicing the wafer according to further some embodiments of the present disclosure may perform the second dicing process DP2 in FIG. 8 using the second light beam L2 which has the wavelength and power smaller than those of the first light beam L1 to cut the portion of the wafer 110, and then may additionally perform the first dicing process DP1 using the first light beam L1 to cut the remaining portion of the wafer 110. Thus, the method for dicing the wafer according to further example embodiments of the present disclosure may improve the efficiency of the dicing process by preventing the portion of the wafer 110 from being unseparated by the dicing process.

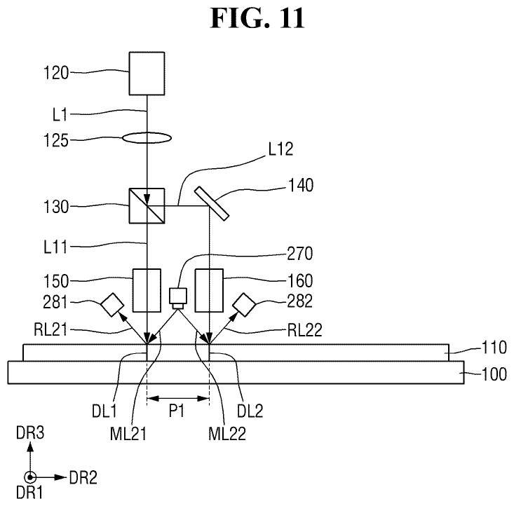

Hereinafter, with reference to FIG. 11, an apparatus for dicing a wafer according to further example embodiments of the present disclosure is described. Following description focuses on differences thereof from the apparatus for dicing the wafer as shown in FIGS. 1 to 4. Duplicative descriptions will not be repeated.

FIG. 11 is a diagram for illustrating an apparatus for dicing a wafer according to further example embodiments of the present disclosure.

Referring to FIG. 11, an apparatus for dicing a wafer according to further example embodiments of the present disclosure may include one sensor 270 and two detectors 281 and 282.

The sensor 270 may be disposed at a side of each of the first objective lens 150 and the second objective lens 160. For example, the sensor 270 may be disposed on a sidewall of each of the first objective lens 150 and the second objective lens 160. For example, the sensor 270 may be disposed between the first objective lens 150 and the second objective lens 160. The sensor 270 may radiate first measuring light ML21 onto the wafer 110 along the first dicing line DL1. Moreover, the sensor 270 may radiate second measuring light ML22 onto the wafer 110 along the second dicing line DL2.

The first detector 281 may be disposed at a side of the first objective lens 150. For example, the first detector 281 may be disposed on the sidewall of the first objective lens 150. The first detector 281 may receive first reflected light RL21 generated when the first measuring light ML21 is reflected from the wafer 110 along the first dicing line DL1. The first detector 281 may measure the thickness in the vertical direction DR3 of the wafer 110 along the first dicing line DL1 using the received first reflected light RL21. The second detector 282 may be disposed at a side of the second objective lens 160. For example, the second detector 282 may be disposed on the sidewall of the second objective lens 160. The second detector 282 may receive second reflected light RL22 generated when the second measuring light ML22 is reflected from the wafer 110 along the second dicing line DL2. The second detector 282 may measure the thickness in the vertical direction DR3 of the wafer 110 along the second dicing line DL2 using the received second reflected light RL22.

For example, the apparatus for dicing the wafer as shown in FIG. 11 may perform a dicing process using the method for dicing the wafer as shown in FIG. 5 and FIG. 6. Moreover, the apparatus for dicing the wafer as shown in FIG. 11 may perform the dicing process using the method for dicing the wafer as shown in FIGS. 7 to 10.

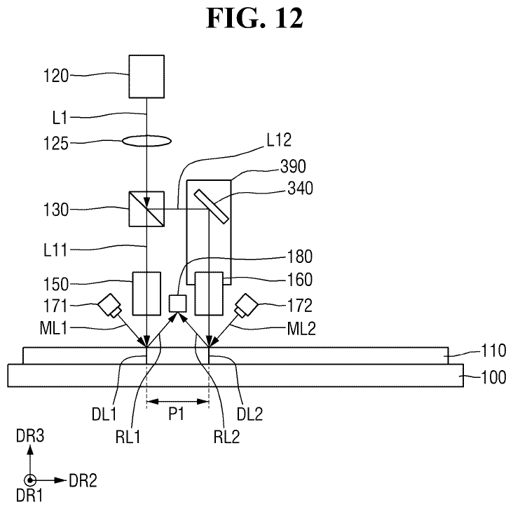

Hereinafter, with reference to FIGS. 12 to 14, an apparatus for dicing a wafer according to still further example embodiments of the present disclosure is described. The following description focuses on differences thereof from the apparatus for dicing the wafer as shown in FIGS. 1 to 4.

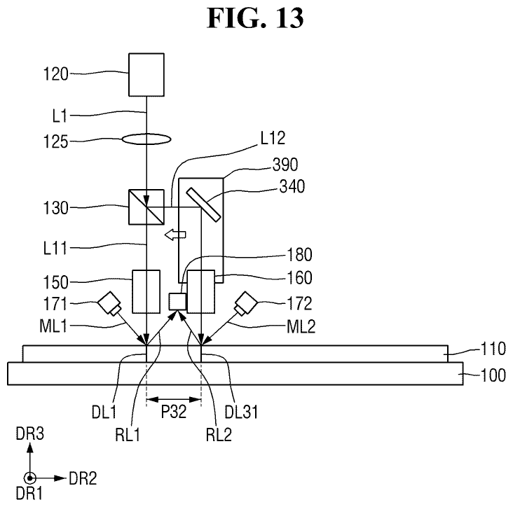

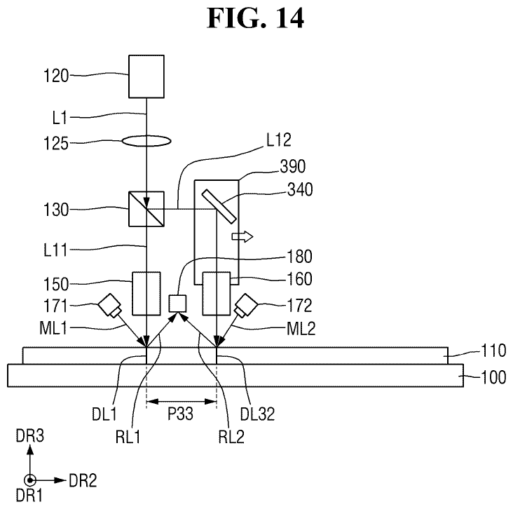

FIG. 12 is a diagram for illustrating an apparatus for dicing a wafer according to still further example embodiments of the present disclosure. FIG. 13 and FIG. 14 are diagrams for illustrating an operation of the apparatus for dicing the wafer according to still further example embodiments of the present disclosure.

Referring to FIGS. 12 to 14, the apparatus for dicing the wafer according to still further example embodiments of the present disclosure may move the second objective lens 160 in the second horizontal direction DR2 using an objective lens transfer unit 390.

For example, the objective lens transfer unit 390 may be connected to the second objective lens 160. For example, the objective lens transfer unit 390 and the second objective lens 160 may move simultaneously in the second horizontal direction DR2. However, the present disclosure is not limited thereto. In further some embodiments, while the objective lens transfer unit 390 is fixed, the second objective lens 160 may be moved in the second horizontal direction DR2.

For example, a reflective mirror 340 may be disposed inside the objective lens transfer unit 390. For example, the second split light beam L12 from the beam splitter 130 may be reflected from the reflective mirror 340 and provided to the second objective lens 160. For example, the objective lens transfer unit 390 and the reflective mirror 340 may be moved simultaneously in the second horizontal direction DR2. However, the present disclosure is not limited thereto.

The apparatus for dicing the wafer according to still further example embodiments of the present disclosure may adjust the position at which the second split light beam L12 is focused on the wafer 110 in the second horizontal direction DR2, such that the spacing P1 in the second horizontal direction DR2 between the first dicing line DL1 and the second dicing line DL2 may be adjusted. For example, referring to FIG. 13, the objective lens transfer unit 390 and the second objective lens 160 may be moved in a direction opposite to the second horizontal direction DR2. A position on which the second split light beam L12 is focused using the second objective lens 160 which has been moved in the opposite direction to the second horizontal direction DR2 may be defined as a first changed dicing line DL31. For example, a spacing P32 in the second horizontal direction DR2 between the first dicing line DL1 and the first changed dicing line DL31 may be smaller than the spacing P1 in FIG. 12 in the second horizontal direction DR2 between the first dicing line DL1 and the second dicing line DL2 in FIG. 12.

For example, referring to FIG. 14, the objective lens transfer unit 390 and the second objective lens 160 may be moved in the second horizontal direction DR2. The position on which the second split light beam L12 is focused using the second objective lens 160 which has been moved in the second horizontal direction DR2 may be defined as a second changed dicing line DL32. For example, a spacing P33 in the second horizontal direction DR2 between the first dicing line DL1 and the second changed dicing line DL32 may be larger than the spacing P1 in FIG. 12 in the second horizontal direction DR2 between the first dicing line DL1 and the second dicing line DL2 in FIG. 12.

That is, as shown in FIG. 13 and FIG. 14, the second objective lens 160 may be moved so that the position of the second dicing line DL2 in FIG. 12 may be changed to the first changed dicing line DL31 or the second changed dicing line DL32. Thus, the spacing in the second horizontal direction DR2 between the first dicing line DL1 and the second dicing line DL2 in FIG. 12 may be adjusted.

For example, the apparatus for dicing the wafer as shown in FIGS. 12 to 14 may perform the dicing process using the method for dicing the wafer as shown in FIGS. 5 and 6. Moreover, the apparatus for dicing the wafer as shown in FIGS. 12 to 14 may perform the dicing process using the method for dicing the wafer as shown in FIGS. 7 to 10.

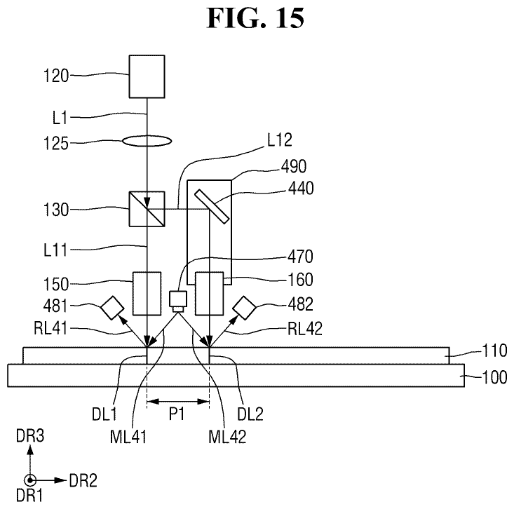

Hereinafter, with reference to FIG. 15, an apparatus for dicing a wafer according to still further example embodiments of the present disclosure is described. The following description focuses on differences thereof from the apparatus for dicing the wafer as shown in FIGS. 1 to 4. Duplicative descriptions will not be repeated.

FIG. 15 is a diagram for illustrating an apparatus for dicing a wafer according to still further example embodiments of the present disclosure.

Referring to FIG. 15, an apparatus for dicing a wafer according to further example embodiments of the present disclosure may include one sensor 470 and two detectors 481 and 482. Moreover, in the apparatus for dicing the wafer according to further example embodiments of the present disclosure, the second objective lens 160 may be moved in the second horizontal direction DR2 using an objective lens transfer unit 490.

The sensor 470 may be disposed at a side of each of the first objective lens 150 and the second objective lens 160. For example, the sensor 470 may be disposed on the sidewall of each of the first objective lens 150 and the second objective lens 160. For example, the sensor 470 may be disposed between the first objective lens 150 and the second objective lens 160. The sensor 470 may radiate first measuring light ML41 onto the wafer 110 along the first dicing line DL1. Moreover, the sensor 470 may radiate second measuring light ML42 onto the wafer 110 along the second dicing line DL2.

The first detector 481 may be disposed at a side of the first objective lens 150. For example, the first detector 481 may be disposed on the sidewall of the first objective lens 150. The first detector 481 may receive first reflected light RL41 generated when the first measuring light ML41 is reflected from the wafer 110 along the first dicing line DL1. The first detector 481 may measure the thickness in the vertical direction DR3 of the wafer 110 along the first dicing line DL1 using the received first reflected light RL41. The second detector 482 may be disposed at a side of the second objective lens 160. For example, the second detector 482 may be disposed on a sidewall of the second objective lens 160. The second detector 482 may receive second reflected light RL42 generated when the second measuring light ML42 is reflected from the wafer 110 along the second dicing line DL2. The second detector 482 may measure the thickness in the vertical direction DR3 of the wafer 110 along the second dicing line DL2 using the received second reflected light RL42.

For example, the objective lens transfer unit 490 may be connected to the second objective lens 160. For example, the objective lens transfer unit 490 and the second objective lens 160 may be moved simultaneously in the second horizontal direction DR2. However, the present disclosure is not limited thereto. In further some embodiments, while the objective lens transfer unit 490 is fixed, the second objective lens 160 may be moved in the second horizontal direction DR2.

For example, a reflective mirror 440 may be disposed inside the objective lens transfer unit 490. For example, the second split light beam L12 from the beam splitter 130 may be reflected from the reflective mirror 440 and provided to the second objective lens 160. For example, the objective lens transfer unit 490 and the reflective mirror 440 may be moved simultaneously in the second horizontal direction DR2. However, the present disclosure is not limited thereto.

The apparatus for dicing the wafer according to still yet further some embodiments of the present disclosure may adjust the position at which the second split light beam L12 is focused on the wafer 110 in the second horizontal direction DR2, such that the spacing P1 in the second horizontal direction DR2 between the first dicing line DL1 and the second dicing line DL2 may be adjusted.

For example, the apparatus for dicing the wafer as shown in FIG. 15 may perform a dicing process using the method for dicing the wafer as shown in FIG. 5 and FIG. 6. Moreover, the apparatus for dicing the wafer as shown in FIG. 15 may perform the dicing process using the method for dicing the wafer as shown in FIGS. 7 to 10.

Although embodiments of the present disclosure have been described with reference to the accompanying drawings, embodiments of the present disclosure are not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. An apparatus for dicing a wafer, the apparatus comprising:
a stage on which the wafer is positioned;
a light source configured to provide a first light beam;
a beam splitter configured to split the first light beam into a first split light beam and a second split light beam;
a first objective lens configured to focus the first split light beam on the wafer, and cut the wafer along a first dicing line extending in a first horizontal direction using the first split light beam; and
a second objective lens spaced apart from the first objective lens in a second horizontal direction different from the first horizontal direction, the second objective lens configured to focus the second split light beam on the wafer, and cut the wafer along a second dicing line extending in the first horizontal direction using the second split light beam,
wherein the second dicing line is spaced apart from the first dicing line in the second horizontal direction,
wherein the apparatus is configured to adjust a position at which the second split light beam is focused on the wafer in the second horizontal direction such that a spacing in the second horizontal direction between the first dicing line and the second dicing line is adjusted, and
wherein the wafer is cut simultaneously along the first dicing line and the second dicing line.

2. The apparatus of claim 1, further comprising a reflective mirror configured to reflect the second split light beam split from the beam splitter and provide the second split light beam to the second objective lens.

3. The apparatus of claim 2, wherein adjusting the spacing in the second horizontal direction between the first dicing line and the second dicing line includes adjusting an angle of the reflective mirror to adjust an angle of the second split light beam to be provided to the second objective lens.

4. The apparatus of claim 1, further comprising an objective lens transfer unit connected to the second objective lens, the objective lens transfer unit configured to move the second objective lens in the second horizontal direction.

5. The apparatus of claim 4, wherein adjusting the spacing in the second horizontal direction between the first dicing line and the second dicing line includes moving the second objective lens in the second horizontal direction using the objective lens transfer unit to adjust the spacing in the second horizontal direction between the first objective lens and the second objective lens.

6. The apparatus of claim 1, further comprising:
a first sensor configured to irradiate a first measuring light to the wafer along the first dicing line;
a second sensor configured to irradiate a second measuring light to the wafer along the second dicing line, the second sensor different from the first sensor; and
a detector configured to:
receive a first reflected light generated when the first measuring light is reflected from the wafer along the first dicing line, and measure a thickness of the wafer along the first dicing line using the received first reflected light, and
receive a second reflected light generated when the second measuring light is reflected from the wafer along the second dicing line, and measure a thickness of the wafer along the second dicing line using the received second reflected light.

7. The apparatus of claim 6, wherein the detector is configured to simultaneously measure the thickness of the wafer along the first dicing line and the thickness of the wafer along the second dicing line.

8. The apparatus of claim 1, further comprising:
a sensor configured to irradiate a first measuring light to the wafer along the first dicing line and irradiate a second measuring light to the wafer along the second dicing line;
a first detector configured to receive a first reflected light generated when the first measuring light is reflected from the wafer along the first dicing line, and measure a thickness of the wafer along the first dicing line using the received first reflected light; and
a second detector configured to receive a second reflected light generated when the second measuring light is reflected from the wafer along the second dicing line, and measure a thickness of the wafer along the second dicing line using the received second reflected light.

9. The apparatus of claim 1,
wherein the light source is further configured to provide a second light beam having a wavelength smaller than a wavelength of the first light beam,
wherein the beam splitter is configured to split the second light beam into a third split light beam and a fourth split light beam,
wherein the first objective lens is configured to cut a portion of the wafer along the first dicing line using the third split light beam, and
wherein the second objective lens is configured to cut a portion of the wafer along the second dicing line using the fourth split light beam.

10. The apparatus of claim 9,
wherein the first objective lens is configured to cut a remaining portion of the wafer along the first dicing line using the first split light beam after cutting the portion of the wafer along the first dicing line using the third split light beam, and
wherein the second objective lens is configured to cut a remaining portion of the wafer along the second dicing line using the second split light beam after cutting the portion of the wafer along the second dicing line using the fourth split light beam.

11. The apparatus of claim 9, wherein the wafer is cut simultaneously along the first dicing line and the second dicing line using the third and fourth split light beams, respectively.

12. An apparatus for dicing a wafer, the apparatus comprising:
a stage on which the wafer is positioned;
a light source configured to provide a first light beam;
a beam splitter configured to split the first light beam into a first split light beam and a second split light beam;
a first objective lens configured to focus the first split light beam on the wafer, and cut the wafer along a first dicing line extending in a first horizontal direction using the first split light beam;
a second objective lens spaced apart from the first objective lens in a second horizontal direction different from the first horizontal direction, the second objective lens configured to focus the second split light beam on the wafer, and cut the wafer along a second dicing line extending in the first horizontal direction using the second split light beam; and
a reflective mirror configured to reflect the second split light beam split from the beam splitter and provide the second split light beam to the second objective lens,
wherein the second dicing line is spaced apart from the first dicing line in the second horizontal direction, and
wherein the apparatus is configured to adjust an angle of the reflective mirror to adjust a spacing in the second horizontal direction between the first dicing line and the second dicing line.

13. The apparatus of claim 12, wherein the wafer is cut simultaneously along the first dicing line and the second dicing line.

14. The apparatus of claim 12, further comprising:
a first sensor configured to irradiate a first measuring light to the wafer along the first dicing line;
a second sensor configured to irradiate a second measuring light to the wafer along the second dicing line, the second sensor different from the first sensor; and
a detector configured to:
receive a first reflected light generated when the first measuring light is reflected from the wafer along the first dicing line, and measure a thickness of the wafer along the first dicing line using the received first reflected light; and
receive a second reflected light generated when the second measuring light is reflected from the wafer along the second dicing line, and measure a thickness of the wafer along the second dicing line using the received second reflected light.

15. The apparatus of claim 14, wherein the detector is configured to simultaneously measure the thickness of the wafer along the first dicing line and the thickness of the wafer along the second dicing line.

16. The apparatus of claim 12, further comprising:
a sensor configured to irradiate a first measuring light to the wafer along the first dicing line and irradiate a second measuring light to the wafer along the second dicing line;
a first detector configured to receive a first reflected light generated when the first measuring light is reflected from the wafer along the first dicing line, and measure a thickness of the wafer along the first dicing line using the received first reflected light; and
a second detector configured to receive a second reflected light generated when the second measuring light is reflected from the wafer along the second dicing line, and measure a thickness of the wafer along the second dicing line using the received second reflected light.

17. A method for dicing a wafer, the method comprising:
loading the wafer onto a stage, wherein the wafer includes a substrate including silicon (Si), a first layer including a material different from a material of the substrate and disposed on an upper surface of the substrate, and a second layer including a material different from the material of the first layer and disposed on an upper surface of the first layer;
providing a first light beam generated from a light source to a beam splitter;
splitting the first light beam into a first split light beam and a second split light beam using the beam splitter;
providing the first split light beam to a first objective lens, and providing the second split light beam to a second objective lens;
focusing the first split light beam on a first dicing line extending in a first horizontal direction on the wafer using the first objective lens, and focusing the second split light beam on a second dicing line extending in the first horizontal direction on the wafer using the second objective lens; and
cutting the wafer along the first dicing line using the first split light beam, and cutting the wafer along the second dicing line using the second split light beam,
wherein the second objective lens is spaced apart from the first objective lens in a second horizontal direction different from the first horizontal direction,
wherein the second dicing line is spaced apart from the first dicing line in the second horizontal direction,
wherein the method adjusts a position at which the second split light beam is focused on the wafer in the second horizontal direction to adjust a spacing in the second horizontal direction between the first dicing line and the second dicing line, and
wherein the wafer is cut simultaneously along the first dicing line and the second dicing line.

18. The method of claim 17,
wherein each of the first and second split light beams is focused on an upper surface of the second layer, and
wherein each of the first and second split light beams sequentially cuts the second layer, the first layer, and the substrate.

19. The method of claim 17, further comprising:
before providing the first light beam generated from the light source to the beam splitter, providing a second light beam generated from the light source to the beam splitter, wherein the second light beam has a wavelength smaller than a wavelength of the first light beam;
splitting the second light beam into a third split light beam and a fourth split light beam using the beam splitter;
focusing the third split light beam onto the first dicing line on the wafer using the first objective lens, and focusing the fourth split light beam onto the second dicing line on the wafer using the second objective lens; and
cutting a portion of the wafer along the first dicing line using the third split light beam, and cutting a portion of the wafer along the second dicing line using the fourth split light beam.

20. The method of claim 17,
wherein providing the second split light beam to the second objective lens includes reflecting the second split light beam split from the beam splitter using a reflective mirror and providing the second split light beam to the second objective lens, and
wherein adjusting the spacing in the second horizontal direction between the first dicing line and the second dicing line includes adjusting an angle of the reflective mirror to adjust the spacing in the second horizontal direction between the first dicing line and the second dicing line.
